(19) United States
(12) Patent Application Publication
(10) Pub. No.: US 2025/0165663 A1
(43) Pub. Date: May 22, 2025

(54) METHODS AND SYSTEMS FOR OBTAINING A 3D PROFILE OF A SAMPLE

(71) Applicant: Applied Materials Israel Ltd., Rehovot (IL)

(72) Inventors: Ido Almog, Rehovot (IL); Ori Golani, Kibbutz Shoval (IL)

(73) Assignee: Applied Materials Israel Ltd., Rehovot (IL)

(21) Appl. No.: 18/951,499

(22) Filed: Nov. 18, 2024

(30) Foreign Application Priority Data
Nov. 20, 2023 (IL) 308702

(51) Int. Cl. G06F 30/17

(52) U.S. Cl. CPC G06F 30/17

(57) ABSTRACT

A method for obtaining a 3D profile of a sample comprising: receiving a first and second sets of data relating to first and second groups of structural parameters from first and second metrology tools, wherein the first and second groups of structural parameters have at least one structural parameter in common; analyzing the first set of data to obtain values for the first group of structural parameters; analyzing the second set of data to obtain values for the second group of structural paraments, wherein values obtained from the analysis of the first set of data for at least some of the common structural features are used to constrain the analysis of the second set of data; and generating a 3D profile of the sample by combining values obtained in the analyses of the first and second sets of data.

### CROSS-REFERENCE TO RELATED APPLICATIONS

This application claims priority to Israeli Patent Application No. 308702, filed Nov. 20, 2023, the entire contents of which is hereby incorporated by reference in its entirety for all purposes.

### TECHNICAL FIELD

The present disclosure relates generally to metrology systems and methods, and in particular to 3D profiling of structures and samples using a combination of different scanning technologies.

### BACKGROUND OF THE INVENTION

Scanning electron microscopy (SEM) is a widely used technique for characterization, and in particular, for imaging of various types of samples, such as but not limited to, metals, ceramics, biological samples, and the like. One of the distinctive features of SEM includes the high spatial resolution thereof, enabling characterizing morphology of the samples, microstructural features and surface defects at the nanoscale levels. In addition to the surface characterization, SEM may be used in conjunction with energy-dispersive X-ray spectroscopy (EDS), to obtain semi-quantitative elemental composition information. While the topmost few nanometers of a sample are analyzed with high-resolution, the depth information provided by SEM is very limited and poses a significant challenge in the analysis of structures and materials. The lack of reliable in-depth information impedes accurate analysis of materials, especially in cases in which a 3D profile of a sample is crucial, such as thin film characterization, quality control and failure analysis. Hence, characterization techniques having high depth sensitivity, such as extreme ultraviolet (EUV) measurements and/or soft X-ray techniques, such as X-ray reflection, are employed to characterize the depth properties thereof. These techniques, however, are typically characterized by poor lateral resolution. Specifically, the resolution of a conventional EUV or soft X-ray microscopy is limited by the numerical aperture of X-ray lenses, limiting the resolution thereof to approximate ranges of tens of nanometers. Such ranges may be too large to directly measure samples, such as modern semiconductor devices.

### BRIEF SUMMARY OF THE INVENTION

According to an aspect of the presently disclosed subject matter, there is provided a method for obtaining a 3D profile of a sample, the method comprising:
receiving a first set of data provided by a first metrology tool and relating to a first group of structural parameters of the sample, the first set of data comprising a first set of measured signals and a first set of operational parameters;
receiving a second set of data provided by a second metrology tool and relating to a second group of structural parameters of the sample, the second set of data comprising a second set of measured signals and a second set of operational parameters, wherein the first and second groups of structural parameters comprise at least one structural parameter in common;
performing a first analysis, the first analysis comprising analyzing the first set of data to obtain values for the first group of structural parameters;
performing a second analysis, the second analysis comprising analyzing the second set of data to obtain values for the second group of structural parameters, wherein values obtained in the first analysis for at least some of the common structural parameters are used to constrain the second analysis; and
generating a substantially complete 3D structural profile of the sample based on combining the values obtained in the first and second analyses.

One of the first and second groups of structural parameters may comprise surface structural parameters, with the other of the first and second groups of structural parameters comprising surface structural parameters and subsurface (i.e., internal) structural parameters.

The first metrology tool may be configured to measure the common structural parameters with higher accuracy than the second metrology tool is.

Values obtained for the common structural parameters in the first analysis may be of substantially high accuracy.

According to some examples, the value of a common structural parameter may be considered to be of “substantially high accuracy” if any further increase in its accuracy provides a resultant increase in the accuracy of values obtained for other structural parameters, such that the resultant increase is not measurably greater (e.g., within an acceptable measurement tolerance) than the increase in the accuracy of the value of the common structural parameter.

According to some examples, the value of a common structural parameter may be considered to be of “substantially high accuracy” if it is within about ±10% of a reference value.

According to some examples, the value of a common structural parameter may be considered to be of “substantially high accuracy” if it is within an acceptable tolerance of a reference value in view of the requirements of the application. The reference value may be a known value of the structural parameter, for example wherein the method is used to facilitate detection of defects, structural anomalies, etc., in the sample.

According to, inter alia, either of the above examples, determining when the value of a common structural parameter is of substantially high accuracy may include repeating some or all steps of the method. One having ordinary skill in the field of the relevant metrology techniques would possess the required level of proficiency to perform the repetition of steps and to determine when a substantially high accuracy has been obtained, for example based on the requirements of the task for which the method is being performed.

The method may further comprise repeating the first and second analyses iteratively, wherein values obtained in each analysis for at least some of the common structural parameters are used to constrain the subsequent analysis.

The method may further comprise applying a unified algorithm wherein the first and second analyses are performed simultaneously.

The unified algorithm may further comprise constraining the first analysis using values obtained in the second analysis for at least some of the common structural parameters.

The complete 3D structural profile may comprise structural parameters relating to width, depth, and/or shape of elements of surface layers; thickness of subsurface layers and/or structures; sample thickness; sample composition; morphology; and/or a phase.

One of the first and second metrology tools may comprise a scanning electron microscope (SEM), and/or the other of the first and second metrology tools may comprise an X-ray metrology tool and/or an extreme ultraviolet (EUV) metrology tool.

The SEM may be a critical dimension SEM.

The SEM may be configured to provide measured signals obtained from scans of different energies, measured signals obtained from scans taken from different angles, measured signals configured to facilitate SEM tomography, measured signals indicating a voltage contrast, and/or measured signals comprising energy-dispersive spectroscopy signals.

The first set of measured signals may be obtained from backscattered electrons, secondary electrons, and/or low-loss electrons.

The X-ray metrology tool and/or EUV metrology tool may be configured to perform soft X-ray metrology, reflectometry, X-ray diffraction, coherent diffractive imaging, ptychography, EUV tomography, and/or X-ray tomography.

The EUV metrology tool may use a light having a wavelength between 1 nm and 50 nm. The X-ray metrology tool may use a light having a wavelength of 1 nm or less.

A sampling rate of the first metrology tool (e.g., an SEM, X-ray metrology tool, EUV metrology tool, etc.) may be lower than a sampling rate of the second metrology tool, the first metrology tool being configured to obtain a limited number of measurements, wherein the second analysis comprises extrapolating a portion of the 3D structural profile sampled by the second metrology tool.

A sampling rate of the first metrology tool (e.g., an SEM, X-ray metrology tool, EUV metrology tool, etc.) may be lower than the sampling rate of the second metrology tool, wherein the second analysis comprises assessing similarities between measurements obtained by the second metrology tool to detect a structural anomaly in the complete 3D structural profile.

The first and/or second analysis may implement one or more algorithms based on physical simulations of the sample, phase retrieval, library searches, gradient descent optimization, and/or machine learning based on measurements of previous samples.

The sample may be a semiconductor structure.

According to another aspect of the presently disclosed subject matter, there is provided a system for obtaining a 3D profile of a sample, the system being configured to execute a code configured to perform the method described above.

It will be appreciated that the method described above, as well as herein the specification and appended claims, is not to be construed as being limited to being performed in the order presented. Ordinal numerals (first, second, etc.) are used for convenience only, and are not intended to indicate a sequence. For example, the first and second analyses may be performed in any suitable order.

Unless otherwise defined, all technical and scientific terms used herein have the same meaning as commonly understood by one of ordinary skill in the art to which this disclosure pertains. In case of conflict, the patent specification, including definitions, governs. As used herein, indefinite articles are to be construed as meaning “at least one” or “one or more” unless otherwise clear from context.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

FIG. 1 is a flowchart of an example of a sequential joint processing method for obtaining a 3D profile of a sample, according to some embodiments;

FIG. 2 is a flowchart of an example of an iterative joint processing method for obtaining a 3D profile of a sample, according to some embodiments; and

FIG. 3 is a flowchart of an example of a unified joint processing method for obtaining a 3D profile of a sample, according to some embodiments.

### DETAILED DESCRIPTION OF THE INVENTION

The principles, uses and implementations of the teachings herein may be better understood with reference to the accompanying description and figures. Upon perusal of the description and figures present herein, one skilled in the art will be able to implement the teachings herein without undue effort or experimentation.

In the following description, various aspects of the invention will be described. For the purpose of explanation, specific details are set forth in order to provide a thorough understanding of the invention. However, it will also be apparent to one skilled in the art that the invention may be practiced without specific details being presented herein. Furthermore, well-known features may be omitted or simplified in order not to obscure the invention.

As used herein, the term “about” may be used to specify a value of a quantity or parameter (e.g., the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, the terms “substantially” and “about” may be interchangeable.

As used herein, according to some embodiments, the term “measured signals” may refer to any signals/data obtained from a first and a second metrology tool. According to some embodiments, the measured signals may refer to raw data (i.e., unprocessed data) and/or to processed data obtained from the first and/or the second metrology tool.

According to some embodiments, one of the first and the second metrology tools may include an SEM and the other of the first and the second metrology tools may include EUV and/or X-ray metrology tools. According to some embodiments, measured signals from the SEM may include, among others, SEM images obtained from a sample/structure. According to some embodiments, the SEM images may include a top view, a side view, a cross-section side view, or any other type of a view of the sample/structure. According to some embodiments, measured signals from the SEM may include, among others, tilted SEM images (i.e., images obtained at non-normal angles). According to some embodiments, the SEM images may be obtained based on using any available SEM-based detection method, such as but not limited to, backscattered electrons, low loss electrons, secondary electrons, and the like, or any combination thereof. According to some embodiments, the measured signals from the SEM may include, among others, images obtained at several different energies, landing energy sweep, and the like. According to some embodiments, measured signals from the SEM may include, among others, SEM tomography. According to some embodiments, measured signals from the SEM may include, among others, voltage contrast images. According to some embodiments, measured signals from the SEM may include, among others, energy-dispersive spectroscopy (EDS) data.

According to some embodiments, the measured signals obtained from the EUV and/or X-ray metrology tools may include, among others, reflectometry, such as X-ray reflectometry (XRR). It may be understood by the skilled in the art that the reflection may be measured at different angles and/or at different wavelengths. According to some embodiments, the measured signals obtained from the EUV and/or X-ray metrology tools may include, among others, diffraction measurements, such as X-ray diffraction (XRD), i.e., measured signals including diffraction patterns at different angles or wavelengths. According to some embodiments, the measured signals obtained from the EUV and/or X-ray metrology tools may include, among others, coherent diffractive imaging (CDI). Put differently, in some embodiments, the measured signals may include signals obtained from imaging methods based on a diffraction pattern of a sample. According to some embodiments, the measured signals obtained from the EUV and/or X-ray metrology tools may include, among others, ptychography, i.e., an imaging method based on a diffraction pattern of a sample obtained with several lateral shifts of the sample. According to some embodiments, the measured signals obtained from the EUV and/or X-ray metrology tools may include, among others, EUV and/or X-ray tomography. According to some embodiments, the measured signals obtained from the EUV and/or X-ray metrology tools may include, among others, signals obtained from soft X-ray tools/methods.

In some embodiments, the term “EUV” may refer to an approximate wavelength range of 1 nm-50 nm. In some embodiments, the term “EUV” may refer to an approximate wavelength range of 1 nm-40 nm, 1 nm-30 nm, 10 nm-50 nm, or 10 nm-40 nm.

In some embodiments, the term “X-ray” may refer to an approximate wavelength range of about 1 nm or less. In some embodiments, the term “X-ray” may refer to an approximate wavelength range of about 0.1 nm-1 nm, 0.5 nm-1 nm, 0.8 nm-1 nm, and the like.

According to some embodiments, the disclosed methods for obtaining a 3D profile of a sample may be utilized for characterization of various types of samples, such as, but not limited to, semiconductor devices, semiconductor device patterns, chips architecture, electric devices, and the like. It is understood by the skilled in the art that the continuous decrease in the dimensions of semiconductor devices requires increase of the resolution and accuracy of metrology tools to characterize the parameters of interest (e.g., structural parameters/properties, such as film thickness, dimensions, dies alignment, presence of defects and/or anomalies, and the like) of the samples. Consequently, often requiring using multiple metrology tools.

SEM and EUV based metrology tools are widely used for characterizing samples. It may be understood by the skilled in the art that measured signals obtained from the SEM (e.g., SEM images) typically include a top view or uppermost images of a structure of a sample with high resolution and high accuracy (e.g., about 1 nm or lower), while providing poor depth information. For example, an inspected sample may include a structure having a plurality of layers, wherein each of the plurality of layers includes a different lateral pattern. Hence, in such scenarios, the obtained SEM images may show the different patterns as a superimposed pattern thereof. Consequently, impeding the extraction of a complete, reliable, and accurate 3D profile of the sample.

It may be further understood by the skilled in the art that EUV and X-ray reflection techniques are characterized by a poor lateral resolution (e.g., about 10 nm or higher), and are typically based on indirect measurements, wherein the light is not tightly focused and the diffraction pattern reflected from a sample is collected.

Currently, the data analysis is typically based on inverse problem algorithms, aiming to determine the structure based on receiving the input light and the scattering patterns resulting therefrom. However, it is generally difficult to solve such inverse problems due to ambiguousness of the solutions. Consequently, the inverse problem algorithms may converge to a wrong solution. Furthermore, in scenarios in which several solutions lead to the same result, the inverse problem algorithms may not be able to distinguish therebetween. In addition, the presence of measurement noise may aggravate and increase the error probability of the inverse problem algorithms.

At least some of the methods according to the presently disclosed subject matter may facilitate combining advantages of each of the metrology tools to obtain a substantially complete 3D profile of a sample having an accuracy, at least in connection with some physical parameters, which is greater than either of the metrology tools would provide on its own. At least some of the methods according to the presently disclosed subject matter may facilitate combining direct measurements of individual structures (e.g., obtained from the SEM) with average properties of the tested sample areas (e.g., obtained from the X-ray/EUV), such that combining thereof yields obtaining improved, more accurate and complete structural parameters of the inspected sample, such as a substantially complete 3D profile thereof.

According to some embodiments, the substantially complete 3D profile may include structural information of the sample, e.g., surface and subsurface properties thereof. According to some embodiments, the substantially complete 3D profile may include, among others, semi-quantitative and/or quantitative elemental analysis of the sample, combined with the structural information thereof. According to some embodiments, the substantially complete 3D structural profile may include at least one of: width, depth, and/or shape of elements of surface layers, thickness of subsurface layers and/or structures, sample thickness, sample composition, morphology, and a phase. As a non-limiting example, the 3D profile of a sample may include a thickness of the sample and/or a thickness of each of layers or components thereof, sample/layer composition, and morphology of the sample. In some embodiments, the substantially complete 3D profile may include determining/identifying presence of structural anomaly in the sample/structure. According to some embodiments, the anomaly may include, among others, any type of discontinuities, defects (e.g., point defects, 2D defects, 3D defects, and the like), presence of contaminations, misalignment, undue variations from design values of width, thickness, material composition, density, and the like, or any combination thereof.

According to some embodiments, the substantially complete 3D profile may include comparison of an inspected sample/structure to a reference structure, such as but not limited to, a comparison to a desired sample/structure (e.g., devoid of defects, anomalies, and the like).

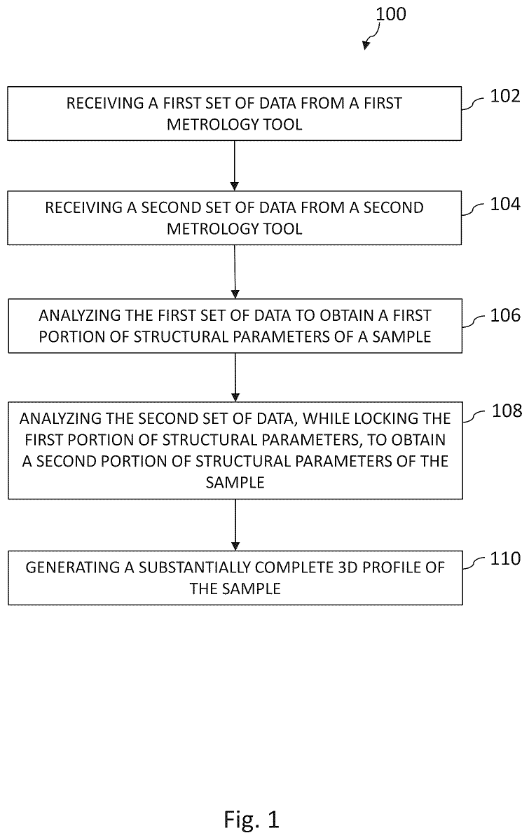

Reference is made to FIG. 1, which shows a flowchart 100 of an example of a sequential joint processing method for obtaining a 3D profile of a sample. According to some embodiments, the joint processing method may be a computer-implemented method.

According to some embodiments, at step 102, the method may include receiving a first set of data from a first metrology tool. According to some embodiments, the first set of data may include a first set of measured signals from the first metrology tool. According to some embodiments, the first set of data may include the first set of measured signals and a first set of operational parameters from the first metrology tool.

According to some embodiments, the first set of data may include a raw (i.e., unprocessed) set of the measured signals obtained from the first metrology tool. Additionally, or alternatively, in some embodiments, the first set of data may include a processed first set of the measured signals.

According to some embodiments, the first set of data may include a single or a plurality of measurements obtained from the same sample. According to some embodiments, wherein the first metrology tool is an SEM, the first set of measured signals may include a plurality of top-view images and/or a plurality of a side view images and/or a plurality of tilted images of the same sample. According to some embodiments, the first set of measured signals obtained from the SEM may include, among others, a plurality of images obtained at different energies and/or at different detection modes. According to some embodiments, the first set of measured signals obtained from the SEM may include, among others, one or more EDS measurements.

According to some embodiments, at step 104, the method may include receiving a second set of data from a second metrology tool. According to some embodiments, the second set of data may include a second set of measured signals and a second set of operational parameters from the second metrology tool.

According to some embodiments, the second set of data may include a raw (i.e., unprocessed) set of the measured signals obtained from the second metrology tool. Additionally, or alternatively, in some embodiments, the second set of data may include a processed second set of the measured signals.

According to some embodiments, the second metrology tool is different than the first metrology tool. In some embodiments, one of the first or the second metrology tools is configured to collect structural properties of subsurface layers and/or structures of a sample, and the other of the first or the second metrology tools is configured to collect structural properties of surface layers of the sample.

Alternatively, in some embodiments, the method may include a step of receiving both the first set of data from the first metrology tool and the second set of data from the second metrology tool.

According to some embodiments, one of the first or the second metrology tools may include an SEM, and wherein the other of the first or the second metrology tools may include at least one of an X-ray and EUV tools.

According to some embodiments, the measured signals from the SEM tool (i.e., the first or the second metrology tool) may include, among others, at least one or more of: SEM tomography, SEM voltage contrast images, landing energy sweep, tilted SEM images, energy-dispersive spectroscopy (EDS) data, and SEM images obtained by one or more of: backscattered electrons, secondary electrons, and low loss electrons.

According to some embodiments, the X-ray and the EUV tools may include, among others, one or more of: soft X-ray, reflectometry, X-ray diffraction, coherent diffractive imaging, ptychography, EUV and/or X-ray tomography.

According to some embodiments, the second set of data may include a single measurement or a plurality of measurements obtained from the same sample. According to some embodiments, the second set of measured signals may include a plurality of EUV scattering patterns obtained from several angles of incidence and/or wavelengths.

According to some embodiments, in scenarios in which a sampling rate of the first metrology tool may be lower than the sampling rate of the second metrology tool, the first metrology tool is configured to obtain a limited number of measurements, to decrease the sampling time.

According to some embodiments, at step 106, the method may include analyzing the first set of data to obtain a first portion of structural parameters of the sample. According to some embodiments, the method may include analyzing the first set of data to obtain a first portion of structural parameters of the sample with a high degree of accuracy. In some embodiments, the first portion of structural parameters of the sample with the high degree of accuracy may be then used to facilitate the analysis executed at step 108. According to some embodiments, the high degree of accuracy may include, among others, scenarios in which the structural parameters to be measured are known within about 10% of their actual values, about 5% of their actual values, or about 1% of their actual values. According to some embodiments, the high degree of accuracy may include, among others, scenarios in which the structural parameters to be measured are known within about 10% or less of their actual values, about 5% or less of their actual values, or about 1% or less of their actual values. As a non-limiting example, if the width or thickness of a certain feature of a semiconductor device is about 10 nm, estimating it with a high degree of accuracy may include an estimation error of less than about 1 nm, less than about 0.5 nm, or less than about 0.1 nm. It is understood by the skilled in the art that the required degree of accuracy that is “sufficiently high” depends on the specific parameter and accuracy requirements.

According to some embodiments, the method may include analyzing the first set of data to obtain a first portion of structural parameters of the sample with a predefined or an initial degree of accuracy, such that the analyzed first portion of structural parameters is configured to facilitate the analysis executed at step 108, thereby obtaining a more accurate outcome. According to some embodiments, the predefined/initial degree of accuracy may include, among others, an allowed estimation error that is one or more of: about 50%, about 40%, about 30%, about 20%, about 10%, about 5%, or about 1%, of the actual values of the parameters to be measured. According to some embodiments, the predefined/initial degree of accuracy may be in one or more ranges of an allowed estimation error of: about 40%-50%, about 30%-40%, about 10%-30%, about 20%-30%, about 10%-20%, and the like.

As a non-limiting example, in a scenario in which the first metrology tool includes an SEM, the first portion of structural parameters may include, among others, widths and shape/morphology of top layers of a sample with a high degree of accuracy (such as, for example, about 10% or less of their actual value), widths and shapes of buried layers with a lower degree of accuracy (such as, for example, in a range of about 10%-20%, 20%-30% of their actual values, and the like), and may be either devoid of thicknesses data of each of the buried layers or may have a low degree of accuracy of the thickness data thereof (such as, for example, in a range of about 40%-50% of the actual thickness).

As another non-limiting example, in a scenario in which the first metrology tool includes an XRR tool, the first portion of structural parameters may include, among others, thickness of layers with a high degree of accuracy (such as, for example, within about 10% or less of the actual thickness), while shape and/or widths of lines at each of the layers may be obtained with a low degree of accuracy (such as, for example, an estimation error in a range of about 10%-30%, in a range of about 20%-40%, and the like).

According to some embodiments, at step 108, the method may include analyzing the second set of data, while locking the first portion of structural parameters of the sample (obtained at step 106), to obtain a second portion of structural parameters of the sample. Thereby, in some embodiments, improving the accuracy of the structural parameters of the sample.

According to some embodiments, the analyzing executed at steps 106 and 108 may include or may be based on physical simulations, algorithms based on library searches, gradient descent optimization, machine learning methods based on measurements of previous samples (e.g., standard samples, previously tested samples, and the like), and the like, or any combination thereof. According to some embodiments, the machine learning based methods may include, among others, linear or non-linear regression methods, estimators based on correlations between structural parameters and the detected signals, or features in the detected signals, artificial neural networks, and the like.

According to some embodiments, the analyzing executed at steps 106 and 108 may include, among others, extrapolating a portion of the 3D structural profile sampled by the first and/or the second metrology tool. As a non-limiting example, in a scenario wherein the sampling rate of the first metrology tool is lower than the sampling rate of the second metrology tool, the first metrology tool may be configured to obtain a limited number of measurements, to decrease the sampling time. Hence, in some embodiments, analyzing may include extrapolating a portion of the 3D profile obtained/sampled by the second metrology tool. In some embodiments, the analyzing may include assessing similarities between measurements obtained by the second metrology tool to detect a structural anomaly in the complete 3D profile of a sample. According to some embodiments, the anomaly may include any type of discontinuities, defects (e.g., point defects, 2D defects, and the like), presence of contaminations, misalignment, undue variations from design values of width, thickness, material composition, density, and the like, or any combination thereof.

According to some embodiments, at step 110, the method may include generating a substantially complete 3D profile of the sample. According to some embodiments generating the substantially complete 3D profile of the sample may include combining the first and the second portions of structural parameters.

According to some embodiments, in a scenario in which the first metrology tool includes an SEM and the second metrology tool includes a diffraction based EUV imaging tool (such as, for example, ptychography, or any other methods), analyzing the first set of data from the first metrology tool may be used as an initial estimation for a phase retrieval algorithm applied thereto. Consequently, improving the accuracy of the generated 3D profile of the sample.

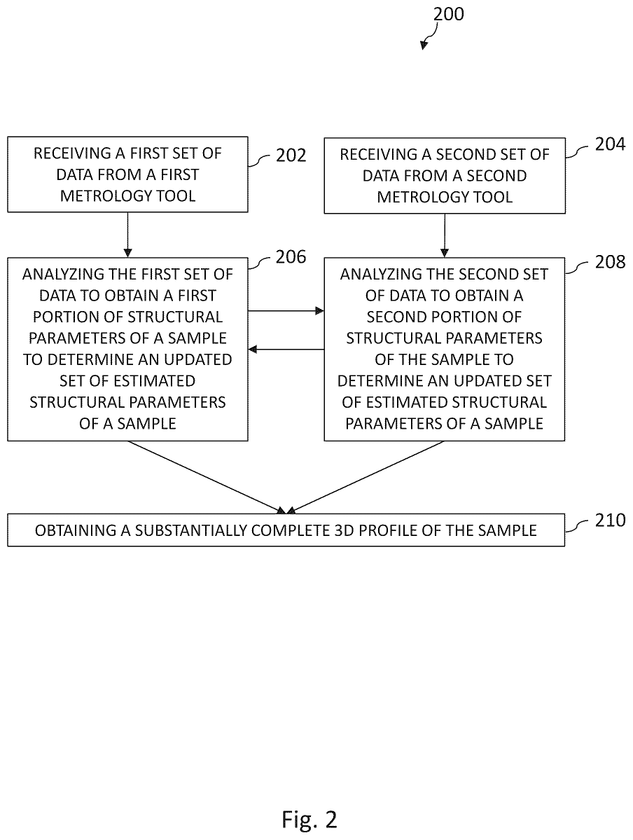

Reference is made to FIG. 2, which shows a flowchart 200 of an example of an iterative joint processing method for obtaining a 3D profile of a sample. According to some embodiments, the iterative joint processing method may be a computer-implemented method.

According to some embodiments, at step 202, the method may include receiving a first set of data from a first metrology tool. According to some embodiments, the first set of data may include a first set of measured signals and a first set of operational parameters from the first metrology tool.

According to some embodiments, at step 204, the method may include receiving a second set of data from a second metrology tool. According to some embodiments, the second set of data may include a second set of measured signals and a second set of operational parameters from the first metrology tool.

In some embodiments, one of the first or the second metrology tools is configured to collect structural properties of subsurface layers and/or structures of a sample, and the other of the first and the second metrology tools is configured to collect structural properties of surface layers of the sample.

Alternatively, or additionally, in some embodiments, the method may include receiving both the first and the second set of data from each of the first and the second metrology tools, respectively.

According to some embodiments, one of the first or the second metrology tools may include an SEM, and the other of the first or the second metrology tools may include at least one of an X-ray and EUV tools.

According to some embodiments, the measured signals from the SEM tool (i.e., the first or the second metrology tool) may include, among others, at least one or more of: SEM tomography, SEM voltage contrast images, landing energy sweep, tilted SEM images, energy-dispersive spectroscopy (EDS) data, and SEM images obtained by one or more of: backscattered electrons, secondary electrons, and low loss electrons.

According to some embodiments, the X-ray and the EUV tools may include one or more of: soft X-ray, reflectometry, X-ray diffraction, coherent diffractive imaging, ptychography, EUV and/or X-ray tomography, and the like, or any combination thereof.

According to some embodiments, and as depicted in flowchart 200, the method may include iteratively analyzing the first and the second data to simultaneously match structural parameters from the first and the second set of measured signals. According to some embodiments, the matching includes repeatedly feeding parameters obtained from the first set of data into the analysis of the second data and vice versa, as elaborated in greater detail in steps 206-208.

According to some embodiments, at step 206, the method may include analyzing the first set of data to obtain a first portion of estimated structural parameters of a sample, thereby obtaining a first updated set of structural parameters. According to some embodiments, and as depicted in FIG. 2, step 206 further includes feeding the first updated set of estimated structural parameters to step 208.

According to some embodiments, at step 208, the method may include analyzing the second set of data to obtain a second portion of structural parameters of the sample, thereby obtaining a second updated set of estimated structural parameters. According to some embodiments, the second updated set of estimated structural parameters may be refined/optimized based, at least in part, on the first updated set of estimated structural parameters. According to some embodiments, and as depicted in FIG. 2, step 208 further includes feeding back the second updated set of estimated structural parameters to step 206. Then, at step 206, the analysis includes using the second updated set of estimated structural parameters together with the first set of data and/or with the (previous) first updated set of estimated structural parameters to refine the structural parameters estimation, thereby obtaining a (new) first updated set of estimated structural parameters. Then, in some embodiments, the (new/refined) first updated set of estimated structural parameters is fed back into step 208, to refine the second updated set of estimated structural parameters.

In some embodiments, steps 206-208 are performed iteratively until a sufficiently accurate parameters estimation is achieved. According to some embodiments, the sufficiently accurate parameters estimation may be achieved upon finding a match between the estimated structural parameters of each of the metrology tools. In some embodiments, the sufficiently accurate parameters estimation may be achieved when the parameter estimation change between successive iteration steps becomes sufficiently small. As a non-limiting example, when the estimation changes are less than about 1% of the estimated values.

According to some embodiments, the analyzing executed at steps 206-208 may include or may be based on physical simulations, algorithms based on library searches, gradient descent optimization, machine learning methods based on measurements of previous samples (e.g., standard samples, previously tested samples, and the like), and the like, or any combination thereof. According to some embodiments, the machine learning based methods may include, among others, linear or non-linear regression methods, estimators based on correlations between structural parameters and the detected signals, or features in the detected signals, artificial neural networks, and the like.

According to some embodiments, the analyzing executed at steps 206-208 may include, among others, extrapolating a portion of the 3D structural profile. As a non-limiting example, in scenarios in which the sampling rate of the first metrology tool is lower than the sampling rate of the second metrology tool, the first metrology tool may be configured to obtain a limited number of measurements, to decrease the sampling time. Hence, in some embodiments, analyzing may include extrapolating a portion of the 3D profile obtained/sampled by the second metrology tool. In some embodiments, the analyzing may include assessing similarities between measurements obtained by the second metrology tool to detect a structural anomaly in the complete 3D profile of a sample. According to some embodiments, the anomaly may include any type of discontinuities, defects (e.g., point defects, 2D defects, and the like), presence of contaminations, misalignment, undue variations from design values of width, thickness, material composition, density, and the like, or any combination thereof.

According to some embodiments, at step 210, the method may include obtaining a substantially complete 3D profile of the sample, by combining the estimated structural parameters. According to some embodiments, the iterative refining of the estimated structural parameters of steps 206-208 increases the accuracy thereof, thereby improving the generated 3D profile of the sample.

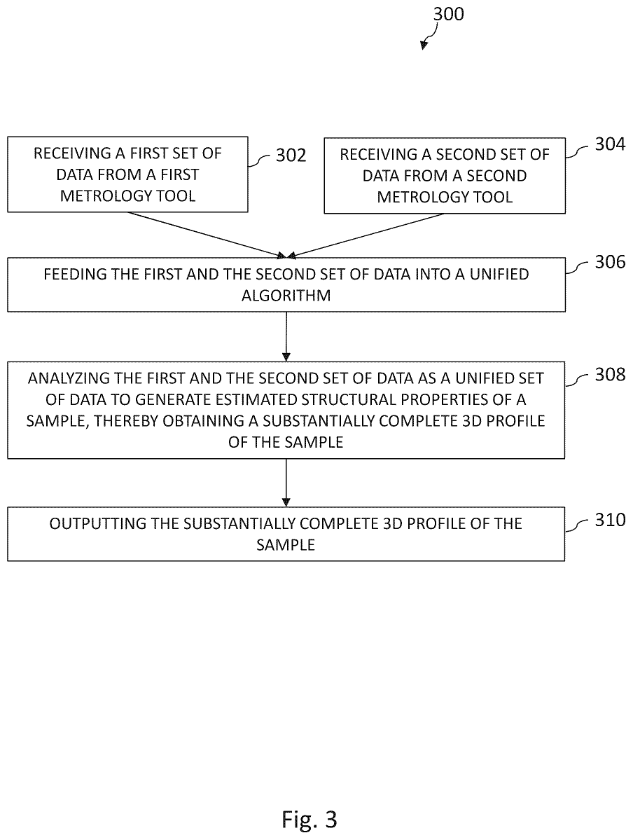

Reference is made to FIG. 3, which shows a flowchart 300 of an example of a unified joint processing method for obtaining a 3D profile of a sample. According to some embodiments, the unified joint processing method may be a computer-implemented method.

According to some embodiments, at step 302, the method may include receiving a first set of data from a first metrology tool. According to some embodiments, the first set of data may include a first set of measured signals and a first set of operational parameters from the first metrology tool.

According to some embodiments, at step 304, the method may include receiving a second set of data from a second metrology tool. According to some embodiments, the second set of data may include a second set of measured signals and a second set of operational parameters from the first metrology tool.

In some embodiments, one of the first or the second metrology tools is configured to collect structural properties of subsurface layers and/or structures of a sample, and the other of the first and the second metrology tools is configured to collect structural properties of surface layers of the sample.

According to some embodiments, one of the first or the second metrology tools may include an SEM, and the other of the first or the second metrology tools may include at least one of an X-ray and EUV tools.

According to some embodiments, the X-ray and the EUV tools may include one or more of: soft X-ray, X-ray reflectometry, X-ray diffraction, coherent diffractive imaging, ptychography, EUV and/or X-ray tomography, and the like, or any combination thereof.

Alternatively, or additionally, in some embodiments, the method may include receiving both the first and the second set of data from each of the first and the second metrology tools, respectively.

According to some embodiments, at step 306, the method may include feeding the first and the second set of data into a unified algorithm.

According to some embodiments, the unified algorithm may include or may be based on physical simulations, algorithms based on library searches, gradient descent optimization, machine learning methods based on measurements of previous samples (e.g., standard samples, previously tested samples, and the like), and the like, or any combination thereof. According to some embodiments, the machine learning based methods may include, among others, linear or non-linear regression methods, estimators based on correlations between structural parameters and the detected signals, or features in the detected signals, artificial neural networks, and the like.

According to some embodiments, at step 308, the method may include analyzing the first and the second set of data as a unified set of data, by applying the unified algorithm to obtain estimated structural parameters of a sample. According to some embodiments, the estimated structural parameters are configured to simultaneously match the first and the second data sets. According to some embodiments, analyzing the first and the second set of data as the unified set of data may be devoid of separating data obtained from the first and/or the second metrology tool.

According to some embodiments, the analyzing executed at step 308 may include, among others, extrapolating a portion of the 3D structural profile. As a non-limiting example, in scenarios in which the sampling rate of the first metrology tool is lower than the sampling rate of the second metrology tool, the first metrology tool may be configured to obtain a limited number of measurements, to decrease the sampling time. Hence, in some embodiments, the analyzing may include extrapolating a portion of the 3D profile obtained/sampled by the second metrology tool. In some embodiments, the analyzing may include assessing similarities between measurements obtained by the second metrology tool to detect a structural anomaly in the complete 3D profile of a sample. According to some embodiments, the anomaly may include any type of discontinuities, defects (e.g., point defects, 2D defects, 3D defects, and the like), presence of contaminations, misalignment, undue variations from design values of width, thickness, material composition, density, and the like, or any combination thereof.

According to some embodiments, at step 310, the method may include outputting the 3D profile of the sample.

In the description and claims of the application, the words “include” and “have”, and forms thereof, are not limited to members in a list with which the words may be associated.

According to an aspect of some embodiments, there is disclosed herein a system for 3D profiling of a sample/structure. According to some embodiments, the system is configured to execute a code configured to execute a sequential joint processing method for obtaining the 3D profile of the sample/structure. According to some embodiments, the system is configured to execute a code configured to receive a first set of data, the first set of data including a first set of measured signals and a first set of operational parameters from a first metrology tool. According to some embodiments, the system is configured to execute a code further configured to receive a second set of data, the second set of data including a second set of measured signals and a second set of operational parameters from a second metrology tool, the second metrology tool is different than the first metrology tool, and wherein one of the first or the second metrology tools is configured to collect structural properties of subsurface layers and/or structures of a sample, and the other of the first and the second metrology tools is configured to collect structural properties of surface layers of the sample.

According to some embodiments of the system, one of the first and the second metrology tools may include an SEM, and the other of the first and the second metrology tools may include an EUV and/or soft X-ray. According to some embodiments, the first or the second set of operational parameters may include SEM operational parameters, such as but not limited to, accelerating voltage, beam current, vacuum level, focal distance, electron gun performance parameters, and the like, or any combination thereof. According to some embodiments, the first or the second set of measured signals may include, among others, secondary electron signals and/or backscattered electron signals obtained from the SEM. As a non-limiting example, the first metrology tool may include an SEM, wherein the first set of measured signals may include SEM images, such as top view images and cross-section images, EDS measurements, and the like, or a combination thereof.

According to some embodiments, a wavelength range of the EUV tool may about 1 nm to about 50 nm, about 10 nm to about 50 nm, about 1 nm to about 40 nm, about 1 nm to about 30 nm, and the like.

According to some embodiments, a wavelength range of the X-ray tool may about 1 nm or less. According to some embodiments, the wavelength range of the X-ray tool may be about 0.1 nm to about 1 nm.

According to some embodiments, the first and/or the second set of measured signals may include unprocessed (i.e., raw) data, as obtained from the first and/or the second metrology tool, Alternatively, or additionally, the first and/or the second set of measured signals may include processed data obtained therefrom. According to some embodiments, the processed data may include, among others, analyzed results obtained from the corresponding metrology tool, and/or processed signals enabling extraction of additional features therefrom.

According to some embodiments of the system, the system is configured to execute a code further configured to analyze the first set of data to obtain a first portion of structural parameters of a sample with a high degree of accuracy; to analyze the second set of data while locking the first portion of structural parameters to obtain a second portion of structural parameters, and to generate a substantially complete 3D profile of the sample based on combining the first and the second portions of structural parameters.

According to some embodiments of the system, the system may include a processing unit. According to some embodiments, the processing unit may include at least one processor. According to some embodiments, the system may include, among others, a non-volatile memory. According to some embodiments, the system may include computer hardware, software, and the like, or a combination thereof.

According to some embodiments of the system, the system may be configured to execute a code configured to output an image depicting the 3D profile of a sample/structure. Additionally, or alternatively, in some embodiments, the system may be configured to execute a code configured to output analyzed values of the 3D profile of the sample/structure, such as, but not limited to: width, depth, and/or shape of elements of top layers, thickness of subsurface layers and/or structures, sample thickness, sample composition, morphology, one or more phases present in the structure/sample, and the like, or any combination thereof.

According to some embodiments, the system may be configured to execute a code based, at least in part on, physical simulations. According to some embodiments, the system may be configured to execute a code based, at least in part on, one or more algorithms based on library searches. According to some embodiments, the system may be configured to execute a code based, at least in part on, gradient-descent-based methods, such as, for example, stochastic gradient descent. According to some embodiments, the system may be configured to execute a code based, at least in part on, signal processing methods. According to some embodiments, the system may be configured to execute a code based, at least in part on, machine learning methods, e.g., based on measurements of previous samples (e.g., previously tested samples by a current system and/or a different system), standard/reference samples, and the like. Non-limiting examples of the relevant machine learning based methods may include, among others, linear or non-linear regression methods, estimators based on correlations between structural parameters and the detected signals, or features in the detected signals, artificial neural networks, and the like.

According to some embodiments, in scenarios in which a sampling rate of the first metrology tool may be lower than the sampling rate of the second metrology tool, the system may be further configured to execute a code configured to output to the first metrology tool instructions to obtain a limited number of measurements. In some embodiments, the system may be configured to execute a code configured to extrapolate a portion of the 3D structural profile sampled by the second metrology tool.

According to some embodiments, in scenarios in which the sampling rate of the first metrology tool may be lower than the sampling rate of the second metrology tool, the system may be further configured to execute a code configured to assess similarities between measurements obtained by the second metrology tool to detect a structural anomaly in the substantially complete 3D structural profile.

According to an aspect of some embodiments, there is disclosed herein an iterative joint processing system for 3D profiling of a sample/structure. According to some embodiments, the system is configured to execute a code configured to execute an iterative joint processing method for obtaining the 3D profile of the sample/structure. According to some embodiments, the system is configured to execute a code configured to receive a first set of data, the first set of data including a first set of measured signals and a first set of operational parameters from a first metrology tool. According to some embodiments, the system is configured to execute a code further configured to receive a second set of data, the second set of data including a second set of measured signals and a second set of operational parameters from a second metrology tool, the second metrology tool is different than the first metrology tool.

According to some embodiments, the system is configured to execute a code further configured to iteratively analyze the first and the second set of data to simultaneously match structural parameters from the first and the second set of measured signals. According to some embodiments, the matching includes repeatedly feeding parameters obtained from the first set of data into the analysis of the second data and vice versa, thereby determining an updated set of estimated structural parameters of a sample, until a substantially complete 3D structural profile of the sample is obtained. According to some embodiments, each of the updated set (at each iteration) of estimated structural parameters of the sample includes an improved/refined values thereof, thereby improving the accuracy of the substantially complete 3D structural profile.

According to some embodiments, the system is configured to execute a code further configured to output the substantially complete 3D profile of the sample/structure.

According to some embodiments of the system, one of the first and the second metrology tools may include an SEM, and the other of the first and the second metrology tools may include an EUV and/or soft X-ray. According to some embodiments, the first or the second set of operational parameters may include SEM operational parameters, such as but not limited to, accelerating voltage, beam current, vacuum level, focal distance, electron gun performance parameters, and the like, or any combination thereof. According to some embodiments, the first or the second set of measured signals may include, among others, secondary electron signals and/or backscattered electron signals obtained from the SEM. As a non-limiting example, the first metrology tool may include an SEM, wherein the first set of measured signals may include SEM images, such as top view images and cross-section images, EDS measurements, and the like, or a combination thereof.

According to some embodiments, a wavelength range of the EUV tool may about 1 nm to about 50 nm, about 10 nm to about 50 nm, about 1 nm to about 40 nm, about 1 nm to about 30 nm, and the like.

According to some embodiments, a wavelength range of the X-ray tool may about 1 nm or less. According to some embodiments, the wavelength range of the X-ray tool may about 0.1 nm to about 1 nm.

According to some embodiments, the first and/or the second set of measured signals may include unprocessed (i.e., raw) data, as obtained from the first and/or the second metrology tool, Alternatively, or additionally, the first and/or the second set of measured signals may include processed data obtained therefrom. According to some embodiments, the processed data may include, among others, analyzed results obtained from the corresponding metrology tool, and/or processed signals enabling extraction of additional features therefrom.

According to some embodiments of the system, the system may include a processing unit. According to some embodiments, the processing unit may include at least one processor. According to some embodiments, the system may include, among others, a non-volatile memory. According to some embodiments, the system may include computer hardware, software, and the like, or a combination thereof.

According to some embodiments of the system, the system may be configured to execute a code configured to output an image depicting the 3D profile of a sample/structure. Additionally, or alternatively, in some embodiments, the system may be configured to execute a code configured to output analyzed values of the 3D profile of the sample/structure, such as, but not limited to: width, depth, and/or shape of elements of top layers, thickness of subsurface layers and/or structures, sample thickness, sample composition, morphology, one or more phases present in the structure/sample, or any combination thereof.

According to some embodiments, the system may be configured to execute a code based, at least in part on, physical simulations. According to some embodiments, the system may be configured to execute a code based, at least in part on, one or more algorithms based on library searches. According to some embodiments, the system may be configured to execute a code based, at least in part on, gradient-descent-based methods, such as, for example, stochastic gradient descent. According to some embodiments, the system may be configured to execute a code based, at least in part on, signal processing methods. According to some embodiments, the system may be configured to execute a code based, at least in part on, machine learning methods, e.g., based on measurements of previous samples (e.g., previously tested samples by a current system and/or a different system), standard/reference samples, and the like. According to some embodiments, the machine learning based methods may include, among others, linear or non-linear regression methods, estimators based on correlations between structural parameters and the detected signals, or features in the detected signals, artificial neural networks, and the like.

According to some embodiments, in scenarios in which a sampling rate of the first metrology tool may be lower than the sampling rate of the second metrology tool, the system may be further configured to execute a code configured to output to the first metrology tool instructions to obtain a limited number of measurements. In some embodiments, the system may be configured to execute a code configured to extrapolate a portion of the 3D structural profile sampled by the second metrology tool.

According to some embodiments, in scenarios in which the sampling rate of the first metrology tool may be lower than the sampling rate of the second metrology tool, the system may be further configured to execute a code configured to assess similarities between measurements obtained by the second metrology tool to detect a structural anomaly in the substantially complete 3D structural profile.

According to an aspect of some embodiments, there is provided a unified joint processing system for obtaining a 3D profile of a sample. According to some embodiments, the unified processing system is configured to execute a code configured to: receive a first set of data, the first set of data including a first set of measured signals and a first set of operational parameters from a first metrology tool; receive a second set of data, the second set of data including a second set of measured signals and a second set of operational parameters from a second metrology tool, wherein one of the first or the second metrology tools comprises an SEM, and wherein the other of the first or the second metrology tools comprises at least one of an X-ray and an EUV tools; feed the first and the second set of data into a unified algorithm; and analyze the first and the second set of data as a unified set of data, by applying the unified algorithm, to obtain estimated structural parameters of a sample, the estimated structural parameters are configured to match simultaneously the first and the second data set. According to some embodiments, the unified algorithm is based, at least in part on, physical simulations, algorithms based on library searches, gradient descent optimization, machine learning methods based on measurements of previous samples, or any combination thereof.

According to some embodiments, the machine learning based methods may include, among others, linear or non-linear regression methods, estimators based on correlations between structural parameters and the detected signals, or features in the detected signals, artificial neural networks, and the like.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

What is claimed is:

1. A method for obtaining a 3D profile of a sample, the method comprising:
receiving a first set of data provided by a first metrology tool and relating to a first group of structural parameters of the sample, the first set of data comprising a first set of measured signals and a first set of operational parameters;
receiving a second set of data provided by a second metrology tool and relating to a second group of structural parameters of the sample, the second set of data comprising a second set of measured signals and a second set of operational parameters, wherein the first and second groups comprise at least one structural parameter in common;
performing a first analysis, the first analysis comprising analyzing the first set of data to obtain values for the first group of structural parameters;
performing a second analysis, the second analysis comprising analyzing the second set of data to obtain values for the second group of structural parameters, wherein values obtained in the first analysis for at least some of the common structural parameters are used to constrain the second analysis; and
generating a substantially complete 3D structural profile of the sample based on combining the values obtained in the first and second analyses.

2. The method according to claim 1, wherein one of the first and second groups of structural parameters comprises surface structural parameters, and the other of the first and second groups of structural parameters comprises surface structural parameters and subsurface structural parameters.

3. The method according to claim 1, wherein the first metrology tool is configured to measure the common structural parameters with higher accuracy than the second metrology tool is.

4. The method according to claim 1, wherein values obtained for the common structural parameters in the first analysis are of substantially high accuracy.

5. The method according to claim 1, further comprising repeating the first and second analyses iteratively, wherein values obtained in each analysis for at least some of the common structural parameters are used to constrain the subsequent analysis.

6. The method according to claim 1, further comprising applying a unified algorithm wherein the first and second analyses are performed simultaneously.

7. The method according to claim 6, wherein the unified algorithm further comprises constraining the first analysis using values obtained in the second analysis for at least some of the common structural parameters.

8. The method according to claim 1, wherein the complete 3D structural profile comprises structural parameters relating to width, depth, and/or shape of elements of surface layers; thickness of subsurface layers and/or structures; sample thickness; sample composition; morphology; and/or a phase.

9. The method according to claim 1, wherein one of the first and second metrology tools comprises a scanning electron microscope (SEM), and/or the other of the first and second metrology tools comprises an X-ray metrology tool and/or an extreme ultraviolet (EUV) metrology tool.

10. The method according to claim 9, wherein the SEM is a critical dimension SEM.

11. The method according to claim 9, wherein the SEM is configured to provide measured signals obtained from scans of different energies, measured signals obtained from scans taken from different angles, measured signals configured to facilitate SEM tomography, measured signals indicating a voltage contrast, and/or measured signals comprising energy-dispersive spectroscopy signals.

12. The method according to claim 9, wherein the first set of measured signals are obtained from backscattered electrons, secondary electrons, and/or low-loss electrons.

13. The method according to claim 9, wherein the X-ray metrology tool and/or EUV metrology tool is configured to perform soft X-ray metrology, reflectometry, X-ray diffraction, coherent diffractive imaging, ptychography, EUV tomography, and/or X-ray tomography.

14. The method according to claim 9, wherein, wherein the EUV metrology tool uses a light having a wavelength between 1 nm and 50 nm, and/or the X-ray metrology tool uses a light having a wavelength of 1 nm or less.

15. The method according to claim 1, wherein a sampling rate of the first metrology tool is lower than a sampling rate of the second metrology tool, the first metrology tool is configured to obtain a limited number of measurements, and the second analysis comprises extrapolating a portion of the 3D structural profile sampled by the second metrology tool.

16. The method according to claim 1, wherein a sampling rate of the first metrology tool is lower than the sampling rate of the second metrology tool, and the second analysis comprises assessing similarities between measurements obtained by the second metrology tool to detect a structural anomaly in the complete 3D structural profile.

17. The method according to claim 1, wherein the first and/or second analysis implements one or more algorithms based on physical simulations of the sample, phase retrieval, library searches, gradient descent optimization, and/or machine learning based on measurements of previous samples.

18. The method according to claim 1, wherein the sample is a semiconductor structure.

19. A system for obtaining a 3D profile of a sample, the system being configured to execute a code configured to perform the method according to claim 1.
